(19) United States
(12) Patent Application Publication
(10) Pub. No.: US 2026/0123081 A1
(43) Pub. Date: Apr. 30, 2026

(54) IMAGE SENSOR

(71) Applicant: SAMSUNG ELECTRONICS CO., LTD., Suwon-si (KR)

(72) Inventors: Hyoun-Jee HA, Suwon-si (KR); Sun Pil YOUN, Suwon-si (KR)

(73) Assignee: SAMSUNG ELECTRONICS CO., LTD., Suwon-si (KR)

(21) Appl. No.: 19/268,169

(22) Filed: Jul. 14, 2025

(30) Foreign Application Priority Data
Oct. 31, 2024 (KR) 10-2024-0152838

(51) Int. Cl. H10F 39/00

(52) U.S. Cl. CPC H10F 39/807; H10F 39/014; H10F 39/811

(57) ABSTRACT

Provided is an image sensor including: a substrate comprising a first surface and a second surface, the first and the second surfaces being on opposite sides of the substrate, a separation pattern within the substrate, the separation pattern defining a plurality of unit pixel regions, wherein the plurality of unit pixel regions comprises a first unit pixel region, a first device isolation pattern and a second device isolation pattern within the substrate, wherein a depth of the second device isolation pattern is greater than a depth of the first device isolation pattern, wherein the separation pattern penetrates the first device isolation pattern, wherein the first and the second device isolation patterns define a first active region on the first unit pixel region, and wherein a first area of the first active region is separated from a second area of the first active region by at least one of the first device isolation pattern and the second device isolation pattern.

### CROSS-REFERENCE TO RELATED APPLICATION

This application claims priority to Korean Patent Application No. 10-2024-0152838, filed on October 31, 2024 in the Korean Intellectual Property Office, the contents of which are hereby incorporated by reference in its entirety.

### BACKGROUND

### Field

The present disclosure relates to an image sensor.

### Description of the Related Art

Image sensors may include charge-coupled device (CCD) image sensors or CMOS image sensors. CMOS image sensors have a relatively simple driving method and allow for the integration of signal processing circuits on a single chip, enabling the miniaturization of products. Additionally, CMOS image sensors have relatively low power consumption, making them well suited to products with limited battery capacity. Furthermore, CMOS image sensors can compatibly utilize CMOS process technology, which may reduce manufacturing costs. Moreover, as technological advancements have enabled the implementation of high resolutions, consumer demand for CMOS image sensors has been increasing.

### SUMMARY

Provided is an image sensor with improved reliability.

According to an aspect of the disclosure, an image sensor includes: a substrate including a first surface and a second surface, the first and the second surfaces being on opposite sides of the substrate; a separation pattern within the substrate, the separation pattern defining a plurality of unit pixel regions, wherein the plurality of unit pixel regions includes a first unit pixel region; a first device isolation pattern within the substrate; a second device isolation pattern within the substrate, the second device isolation pattern including a first auxiliary device isolation pattern in a first direction; and a second auxiliary device isolation pattern in a second direction intersecting the first direction, wherein the first auxiliary device isolation pattern is adjacent to the second auxiliary device isolation pattern, wherein a depth of the second device isolation pattern is greater than a depth of the first device isolation pattern, wherein the separation pattern penetrates the first device isolation pattern, wherein the first and the second device isolation patterns define a first active region on the first unit pixel region, and wherein a first area of the first active region is separated from a second area of the first active region by the first auxiliary device isolation pattern and the second auxiliary device isolation pattern.

According to an aspect of the disclosure, an image sensor includes: a substrate including a first surface and a second surface, the first and the second surfaces being on opposite sides of the substrate; a separation pattern within the substrate, the separation pattern defining a plurality of unit pixel regions, wherein the plurality of unit pixel regions includes a first unit pixel region; a first device isolation pattern within the substrate; and a second device isolation pattern within the substrate, wherein the first and the second device isolation patterns define an active region on the first unit pixel region, wherein the separation pattern penetrates the first device isolation pattern, wherein, from a planar perspective, the first unit pixel region includes: the second device isolation pattern adjacent to an impurity region in a first direction; and a gate electrode adjacent to the impurity region, and wherein a depth of the second device isolation pattern is greater than a depth of the first device isolation pattern.

According to an aspect of the disclosure, an image sensor includes: a substrate including a first surface and a second surface, the first and the second surfaces being on opposite sides of the substrate; a pixel separation pattern within the substrate, the pixel separation pattern defining a plurality of unit pixel regions; and a plurality of first device isolation patterns; and a plurality of second device isolation patterns within the substrate, the plurality of second device isolation patterns including a first auxiliary device isolation pattern and a second auxiliary device isolation pattern, wherein the plurality of first device isolation patterns and a plurality of second device isolation patterns defining active regions on the plurality of unit pixel regions, wherein the plurality of unit pixel regions includes a first unit pixel region and a second unit pixel region separated by the pixel separation pattern, wherein the first unit pixel region includes a first active region, wherein the second unit pixel region includes a second active region, wherein, in a first cross-section passing through the first unit pixel region and the second unit pixel region, the pixel separation pattern penetrates a first device isolation pattern of the plurality of first device isolation patterns, wherein the first active region includes a first area and a second area separated by the first auxiliary device isolation pattern, wherein the second active region includes a third area and a fourth area separated by the second auxiliary device isolation pattern, wherein a depth of the plurality of second device isolation patterns is greater than a depth of the first device isolation pattern, wherein a minimum width of the first device isolation pattern is greater than a minimum width of the plurality of second device isolation patterns, wherein the first device isolation pattern includes a first liner layer, a second liner layer, and a gap-fill layer, wherein each of the plurality of second device isolation patterns includes a material that is different from a material of the first liner layer and the same as a material of the second liner layer, wherein the second liner layer includes any one of SiN, SiCN, or SiOCN, and wherein an angle formed between an inclined surface of the first device isolation pattern and the first surface is smaller than an angle formed between inclined surfaces of the plurality of second device isolation patterns and the first surface.

Aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of certain embodiments of the present disclosure will become more apparent from the following description taken in conjunction with the accompanying drawings, in which:

FIG. 1 is a circuit diagram illustrating a unit pixel region of a pixel array;

FIG. 2 is a plan view illustrating an image sensor according to one or more embodiments;

FIG. 3 is a cross-sectional view taken along line I-I’ of FIG. 2;

FIG. 4 and FIG. 5 are an enlarged view illustrating region M of FIG. 2;

FIG. 6 is a cross-sectional view taken along line A-A’ of FIG. 4;

FIG. 7 is an enlarged view illustrating region N of FIG. 6;

FIGS. 8, 9, 10, 11, 12, 13, 14, 15, 16, 17 and 18 are enlarged views of region N of FIG. 6, illustrating a method of manufacturing an image sensor according to one or more embodiments;

FIGS. 19, 20, 21, 22 and 23 are enlarged views of region N of FIG. 6, illustrating a method of manufacturing an image sensor according to one or more embodiments;

FIGS. 24, 25, 26, 27, 28 and 29 are enlarged views of region N of FIG. 6, illustrating a method of manufacturing an image sensor according to one or more embodiments;

FIG. 30 is an enlarged view of region M of FIG. 2;

FIG. 31 is a cross-sectional view taken along line B-B’ of FIG. 30;

FIG. 32 is an enlarged view of region M of FIG. 2;

FIG. 33 is a cross-sectional view taken along line D-D’ of FIG. 32; and

FIG. 34 is a cross-sectional view taken along line E-E’ of FIG. 32.

### DETAILED DESCRIPTION

One or more embodiments of the present disclosure will hereinafter be described in detail with reference to the accompanying drawings. The same reference numerals are used for the same components in the drawings, and redundant descriptions thereof will be omitted.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

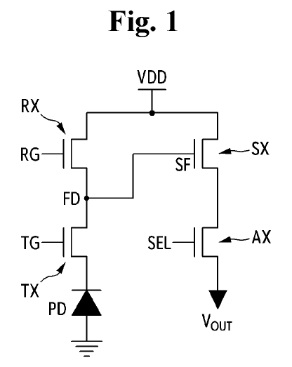

FIG. 1 is a circuit diagram illustrating a unit pixel region of a pixel array. For reference, FIG. 1 may represent a four-transistor (4T) structure of a unit pixel region constituting a pixel array.

Referring to FIG. 1, the pixel array may include a photoelectric conversion region PD, a transfer transistor TX, a floating diffusion region FD, a reset transistor RX, a source follower transistor SX, and a selection transistor AX.

The photoelectric conversion region PD may generate charge in proportion to the amount of light incident from the outside. The photoelectric conversion region PD may be a photodiode that includes an n-type impurity region and a p-type impurity region. The photoelectric conversion region PD may be coupled to the transfer transistor TX that transfers the charge generated and accumulated to the floating diffusion region FD. The floating diffusion region FD, which converts charge into a voltage, may have parasitic capacitance that allows charge to be cumulatively stored.

One end of the transfer transistor TX may be connected to one photoelectric conversion region PD, and the other end of the transfer transistor TX may be connected to the floating diffusion region FD. The transfer transistor TX may be configured as a transistor driven by a predetermined bias, for example, transfer signals. The transfer signals may be applied through a transfer gate TG. The transfer gate TG may be a vertical transfer gate VTG. The transfer transistor TX may transfer the charge generated in the photoelectric conversion region PD to the floating diffusion region FD according to the transfer signals.

The source follower transistor SX may amplify changes in the electrical potential of the floating diffusion region FD, which has received charge from the photoelectric conversion region PD, and output these changes to an output line V_{OUT}. When the source follower transistor SX is turned on, a predetermined electrical potential provided to the drain of the source follower transistor SX, such as a power supply voltage VDD, may be delivered to the drain region of the selection transistor AX. A source follower gate SF of the source follower transistor SX may be connected to the floating diffusion region FD.

The selection transistor AX may select a unit pixel region to be read out on a row-by-row basis. The selection transistor AX may be configured as a transistor driven by a predetermined bias, for example, a row selection signal applied via a selection line. The row selection signal may be applied through a selection gate SEL.

The reset transistor RX may periodically reset the floating diffusion region FD. The reset transistor RX may be configured as a transistor driven by a predetermined bias, for example, a reset signal applied via a reset line. The reset signal may be applied through a reset gate RG. When the reset transistor RX is turned on by the reset signal, a predetermined electrical potential provided to the drain of the reset transistor RX, such as the power supply voltage VDD, may be delivered to the floating diffusion region FD.

FIG. 1 illustrates a configuration in which one floating diffusion region FD is electrically connected to one transfer transistor TX, but the present disclosure is not limited thereto. For example, one floating diffusion region FD may be electrically connected to multiple transfer transistors TX. Accordingly, the integration density of an image sensor according to one or more embodiments can be improved.

In one or more embodiments, as the area of each unit pixel region becomes smaller, the photoelectric conversion region PD and the transfer transistor TX may be formed on one semiconductor chip, while the reset transistor RX, the source follower transistor SX, and the selection transistor AX may be formed on another semiconductor chip. These semiconductor chips may be aligned to constitute a unit pixel region.

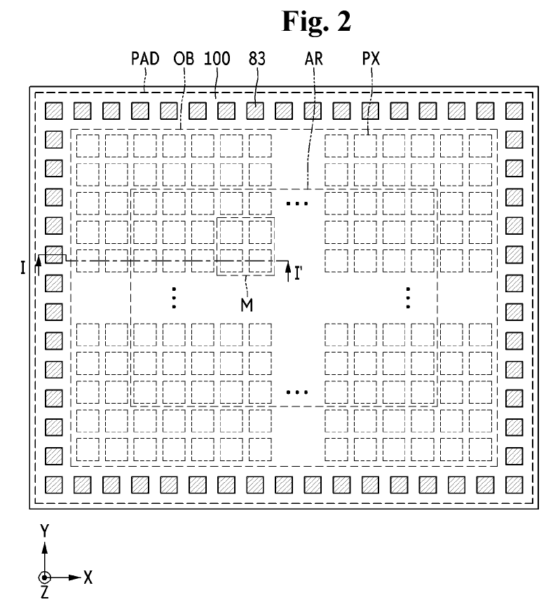

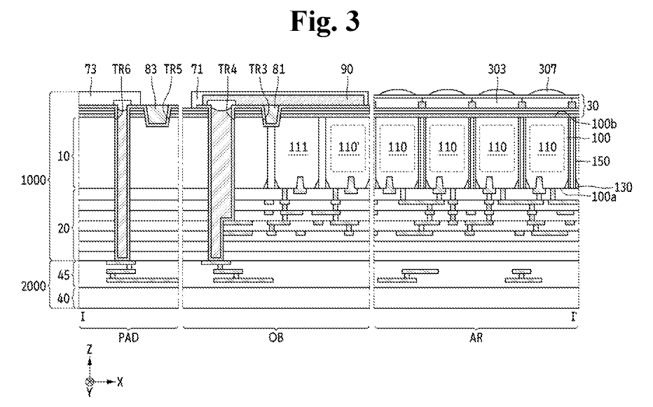

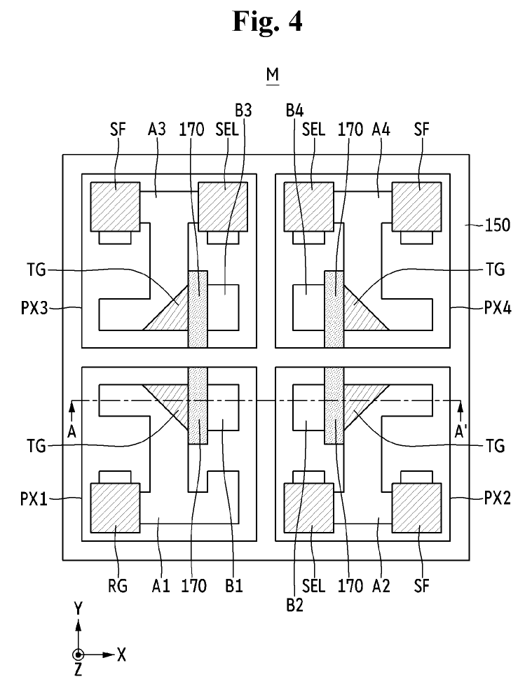

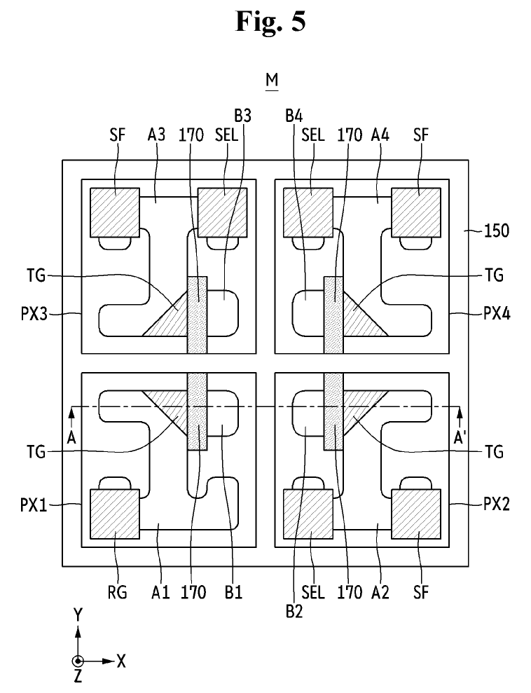

FIG. 2 is a plan view illustrating an image sensor according to one or more embodiments. FIG. 3 is a cross-sectional view taken along line I-I’ of FIG. 2. Referring to FIGS. 2 and 3, the image sensor according to one or more embodiments may include a sensor chip 1000 and a logic chip 2000. The sensor chip 1000 may include a photoelectric conversion layer 10, a first wiring layer 20, and a light-transmitting layer 30. The photoelectric conversion layer 10 may include a substrate 100, a separation pattern 150, a first device isolation pattern 130, a second device isolation pattern 170 (see, e.g., FIGS. 4 and 5), and photoelectric conversion regions 110 provided in the substrate 100. Light incident from the outside may be converted into electrical signals in the photoelectric conversion regions 110. From a planar perspective, the substrate 100 may include a pixel array region AR, an optical black region OB, and a pad region PAD. The pixel array region AR may be located at the center of the substrate 100 from a planar perspective. The pixel array region AR may include a plurality of unit pixel regions PX. The unit pixel regions PX may output photoelectric signals from incident light. The unit pixel regions PX may form rows and columns and may be arranged in a two-dimensional (2D) matrix. The columns may be parallel to a first direction Y. The rows may be parallel to a second direction X. In this disclosure, the first direction Y may be parallel to a first surface 100a of the substrate 100. The second direction X may also be parallel to the first surface 100a of the substrate 100 but may differ from the first direction Y. For example, the second direction X may be substantially perpendicular to the first direction Y. A third direction Z may be substantially perpendicular to the first surface 100a of the substrate 100. From a planar perspective, the pad region PAD may be provided at the edge of the substrate 100 and may surround the pixel array region AR. Second pad terminals 83 may be provided on the pad region PAD. The second pad terminals 83 may output electrical signals generated in the unit pixel regions PX to the outside. Alternatively, external electrical signals or voltages may be delivered to the unit pixel regions PX through the second pad terminals 83. Since the pad region PAD is located at the edge of the substrate 100, the second pad terminals 83 can be more easily connected to external components. The optical black region OB may be located between the pixel array region AR and the pad region PAD of the substrate 100. The optical black region OB may surround the pixel array region AR from a planar perspective and may include a plurality of dummy regions 111. Signals generated in the dummy regions 111 may be used as information to remove process noise later. The pixel array region AR of the image sensor according to one or more embodiments will hereinafter be described in further detail with reference to FIGS. 4 through 34.

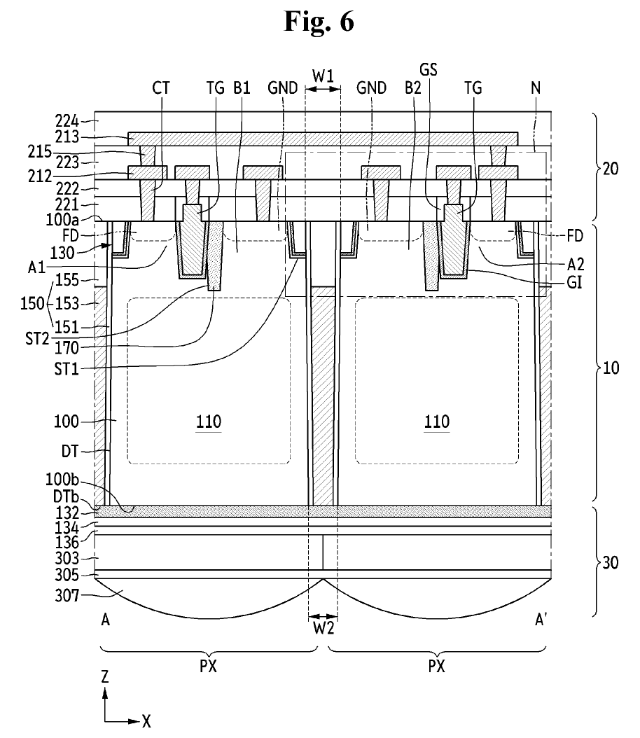

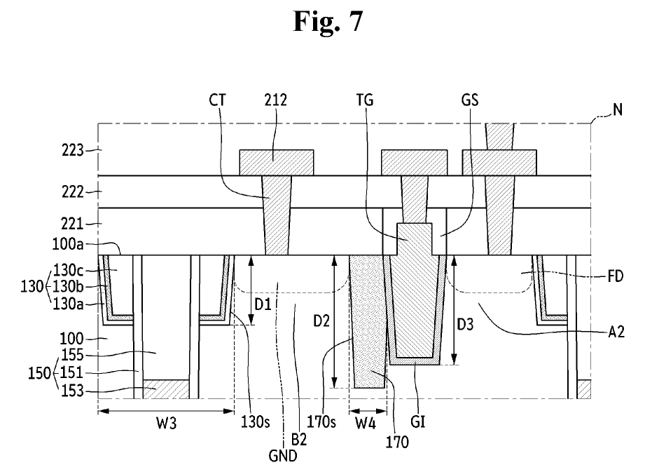

FIGS. 4 and 5 are enlarged view illustrating region M of FIG. 2. FIG. 6 is a cross-sectional view taken along line A-A’ of FIG. 4. FIG. 7 is an enlarged view illustrating region N of FIG. 6.

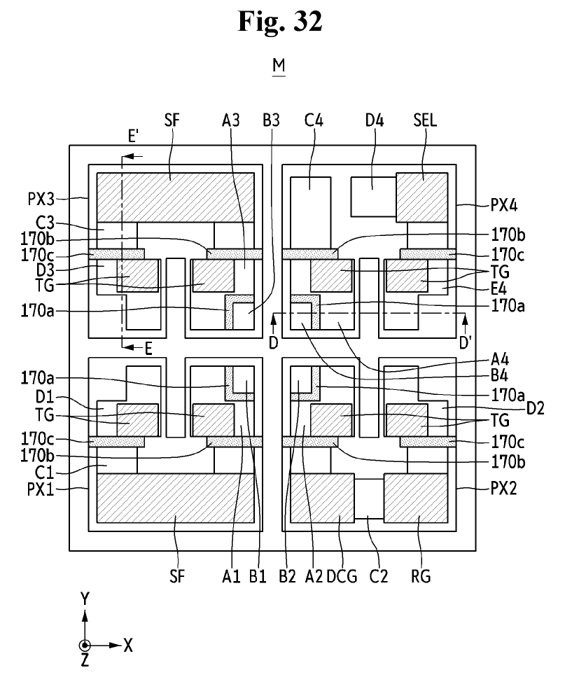

Referring to FIGS. 4, 6 and 7, the image sensor according to one or more embodiments may include the photoelectric conversion layer 10, gate electrodes (TG, SEL, SF, RG, and DCG (see, e.g., FIG. 32 for gate electrode DCG)), the first wiring layer 20, and the light-transmitting layer 30. The photoelectric conversion layer 10 may include the substrate 100, the separation pattern 150, the first device isolation pattern 130, and the second device isolation pattern 170.

The substrate 100 may have the first surface 100a and a second surface 100b opposite to the first surface 100a. Light may be incident on the second surface 100b of the substrate 100. The first wiring layer 20 may be disposed on the first surface 100a of the substrate 100, and the light-transmitting layer 30 may be disposed on the second surface 100b of the substrate 100. The substrate 100 may be a semiconductor substrate or a silicon-on-insulator (SOI) substrate. The semiconductor substrate may include, for example, a silicon (Si) substrate, a germanium (Ge) substrate, or a silicon-germanium (SiGe) substrate. The substrate 100 may include impurities of a first conductivity type. For example, the impurities of the first conductivity type may include p-type impurities such as aluminum (Al), boron (B), indium (In), and/or gallium (Ga).

The substrate 100 may include a plurality of first through fourth unit pixel regions PX1 through PX4 defined by the separation pattern 150. The first through fourth first through fourth unit pixel regions PX1 through PX4 may be arranged in a matrix form along the first direction Y and the second direction X, which intersect each other. The substrate 100 may include the photoelectric conversion regions 110. The photoelectric conversion regions 110 may be respectively provided in the first through fourth first through fourth unit pixel regions PX1 through PX4 in the substrate 100. The photoelectric conversion regions 110 may perform the same functions and roles as the photoelectric conversion region PD of FIG. 1. The photoelectric conversion regions 110 may be doped regions of a second conductivity type in the substrate 100. The second conductivity type may be opposite to the first conductivity type. The second conductivity type may include n-type impurities such as phosphorus (P), arsenic (As), bismuth (Bi), and/or antimony (Sb). In one example, the photoelectric conversion regions 110 may be adjacent to the second surface 100b of the substrate 100. The photoelectric conversion regions 110 may be disposed closer to the second surface 100b than to the first surface 100a of the substrate 100. In another example, the photoelectric conversion regions 110 may be adjacent to the first surface 100a of the substrate 100. The photoelectric conversion regions 110 may be disposed closer to the first surface 100a than to the second surface 100b. For example, each of the photoelectric conversion regions 110 may include a first area adjacent to the first surface 100a and a second area adjacent to the second surface 100b. A difference may arise in impurity concentration between the first and second areas of each of the photoelectric conversion regions 110. Thus, the photoelectric conversion regions 110 may have a potential gradient between the first and second surfaces 100a and 100b of the substrate 100. Alternatively, the photoelectric conversion regions 110 may not have a potential gradient between the first and second surfaces 100a and 100b.

The substrate 100 and the photoelectric conversion regions 110 may form photodiodes. Specifically, photodiodes may be formed by p-n junctions between the substrate 100 of the first conductivity type and the photoelectric conversion regions 110 of the second conductivity type. The photoelectric conversion regions 110 forming the photodiodes may generate and accumulate photocharge in proportion to the intensity of incident light.

In one or more embodiments, the separation pattern 150 may be provided in the substrate 100 to define the first through fourth unit pixel regions PX1 through PX4. For example, the separation pattern 150 may be provided between the first through fourth unit pixel regions PX1 through PX4 of the substrate 100. The separation pattern 150 may separate the first through fourth unit pixel regions PX1 through PX4 from one another. From a planar perspective, the separation pattern 150 may have a lattice structure. From a planar perspective, the separation pattern 150 may completely surround each of the first through fourth unit pixel regions PX1 through PX4. The separation pattern 150 may be provided in a deep trench DT. The deep trench DT may be recessed from the first surface 100a of the substrate 100. The separation pattern 150 may extend from the first surface 100a toward the second surface 100b of the substrate 100. The separation pattern 150 may be a deep trench isolation (DTI) film. The separation pattern 150 may penetrate the substrate 100. The vertical height of the separation pattern 150 may be substantially the same as the vertical thickness of the substrate 100. For example, the width of the separation pattern 150 may gradually decrease from the first surface 100a toward the second surface 100b of the substrate 100. The width of the separation pattern 150 at the first surface 100a may be referred to as a first width W1, and the width at the second surface 100b may be referred to as a second width W2. That is, the first width W1 may be greater than the second width W2.

The separation pattern 150 may penetrate the first device isolation pattern 130. At least a portion of the first device isolation pattern 130 may contact the upper sidewalls of the separation pattern 150. The sidewalls and lower surface of the first device isolation pattern 130 and the sidewalls of the separation pattern 150 may have a stepped structure. The depth of the first device isolation pattern 130 may be less than the depth of the separation pattern 150.

The separation pattern 150 may include a first isolation pattern 151, a second isolation pattern 153, and a capping pattern 155. The first isolation pattern 151 may be provided along the sidewalls of the deep trench DT. For example, the first isolation pattern 151 may include an Si-based insulating material (e.g., silicon nitride, silicon oxide, and/or silicon oxynitride) and/or a high-k material (e.g., hafnium oxide and/or aluminum oxide). In one or more embodiments, the first isolation pattern 151 may include multiple layers, formed of different materials. The first isolation pattern 151 may have a refractive index lower than that of the substrate 100. Accordingly, the first isolation pattern 151 can prevent or reduce crosstalk between the unit pixel regions PX of the substrate 100.

The second isolation pattern 153 may be provided inside the first isolation pattern 151. For example, the sidewalls of the second isolation pattern 153 may be surrounded by the first isolation pattern 151. The first isolation pattern 151 may be positioned between the second isolation pattern 153 and the substrate 100. The second isolation pattern 153 may be spaced apart from the substrate 100 by the first isolation pattern 151. Accordingly, during the operation of the image sensor according to one or more embodiments, the second isolation pattern 153 may be electrically isolated from the substrate 100. The second isolation pattern 153 may include a crystalline semiconductor material, such as polycrystalline Si. In one or more embodiments, the second isolation pattern 153 may further include a dopant, such as impurities of the first or second conductivity type. For example, the second isolation pattern 153 may include doped polycrystalline Si. In one or more embodiments, the second isolation pattern 153 may include an undoped crystalline semiconductor material. For example, the second isolation pattern 153 may include an undoped polycrystalline Si. The term “undoped” may mean that no intentional doping process has been performed. The dopant may include an n-type dopant and a p-type dopant.

The capping pattern 155 may be provided on the upper surface of the second isolation pattern 153. The capping pattern 155 may be disposed adjacent to the first surface 100a of the substrate 100. The upper surface of the capping pattern 155 may be coplanar with the first surface 100a of the substrate 100. The lower surface of the capping pattern 155 may be substantially the same as the upper surface of the second isolation pattern 153. The capping pattern 155 may include a non-conductive material. For example, the capping pattern 155 may include an Si-based insulating material (e.g., silicon nitride, silicon oxide, and/or silicon oxynitride) and/or a high-k material (e.g., hafnium oxide and/or aluminum oxide). Accordingly, the separation pattern 150 may prevent photocharge generated by incident light in each unit pixel region PX from drifting randomly into adjacent unit pixel regions PX. In other words, the separation pattern 150 can prevent crosstalk between the first through fourth unit pixel regions PX1 through PX4.

The first device isolation pattern 130 may be provided in the substrate 100. For example, the first device isolation pattern 130 may be provided in a first shallow trench ST1 recessed from the first surface 100a of the substrate 100. The first device isolation pattern 130 may be a shallow trench isolation (STI) film. The lower surface of the first device isolation pattern 130 may be provided in the substrate 100.

The width of the first device isolation pattern 130 may gradually decrease from the first surface 100a toward the second surface 100b of the substrate 100. The lower surface of the first device isolation pattern 130 may be vertically spaced apart from the photoelectric conversion regions 110.

The first device isolation pattern 130 may include a first liner layer 130a, a second liner layer 130b, and a gap-fill layer 130c, and the first liner layer 130a, the second liner layer 130b, and the gap-fill layer 130c may include different materials.

The first liner layer 130a may be disposed in the first shallow trench ST1. The first liner layer 130a may be disposed on the sidewalls and the lower surface of the first shallow trench ST1. The first liner layer 130a may extend along the sidewalls and the lower surface of the first shallow trench ST1.

The first liner layer 130a may include an insulating material. In one or more embodiments, the first liner layer 130a may include silicon oxide (SiO).

The second liner layer 130b may be disposed on the first liner layer 130a. The second liner layer 130b may extend along the upper surface of the first liner layer 130a.

The second liner layer 130b may include an insulating material. In one or more embodiments, the second liner layer 130b may include silicon nitride (SiN), silicon carbonitride (SiCN), or silicon oxycarbonitride (SiOCN).

The gap-fill layer 130c may be disposed on the second liner layer 130b. In one or more embodiments, the gap-fill layer 130c may include SiO.

The second device isolation pattern 170 may be provided in the substrate 100. For example, the second device isolation pattern 170 may be provided in a second shallow trench ST2. The second shallow trench ST2 may be recessed from the first surface 100a of the substrate 100. The lower surface of the second device isolation pattern 170 may be provided in the substrate 100.

The width of the second device isolation pattern 170 may gradually decrease from the first surface 100a toward the second surface 100b of the substrate 100. The lower surface of the second device isolation pattern 170 may be vertically spaced apart from the photoelectric conversion regions 110.

The second device isolation pattern 170 may include an insulating material. In one or more embodiments, the second device isolation pattern 170 may be formed of a material different from the first liner layer 130a of the first device isolation pattern 130 but the same as the second liner layer 130b. The second device isolation pattern 170 may include SiN.

The first and second shallow trenches ST1 and ST2 may partially penetrate the substrate 100 and may not completely penetrate the substrate 100. That is, the depths of the first and second shallow trenches ST1 and ST2 in the third direction Z may be less than the depth of the deep trench DT in the third direction Z.

The width of the first device isolation pattern 130 may be greater than the width of the second device isolation pattern 170. In this specification, the term “width” may refer to the length in the direction in which active regions are spaced apart or separated by the first device isolation pattern 130 or the second device isolation pattern 170. The term “width” may also refer to the length measured on the first surface 100a of the substrate 100. In one or more embodiments, the first device isolation pattern 130 may have a third width W3, and the second device isolation pattern 170 may have a fourth width W4. The minimum value of the third width W3 may be greater than the minimum value of the fourth width W4. For example, the third width W3 may range from 40 nm to 60 nm, and the fourth width W4 may range from 20 nm to 40 nm. Through this, the area of active regions B1 through B4 within the first through fourth unit pixel regions PX1 through PX4 may be maximized, thereby providing an image sensor with improved reliability.

The depth of the first device isolation pattern 130 may be less than the depth of the second device isolation pattern 170. In one or more embodiments, the first device isolation pattern 130 may have a first depth D1, and the second device isolation pattern 170 may have a second depth D2. The first depth D1 may be less than the second depth D2. For example, the first depth D1 may range from 250 nm to 350 nm, and the second depth D2 may be greater than 250 nm to 350 nm.

In one or more embodiments, the depth of the second device isolation pattern 170 may be the second depth D2, and the depth of the transfer gate TG may be the third depth D3. The second depth D2 may be greater than the third depth D3. However, the embodiments of the present disclosure are not limited to this configuration. The second depth D2 may also be less than the third depth D3. For example, the third depth D3 may range from 420 nm to 450 nm, and the second depth D2 may be greater or less than 420 nm to 450 nm.

In one or more embodiments, the angle formed between an inclined surface 130s of the first device isolation pattern 130 and the first surface 100a of the substrate 100 may be smaller than the angle formed between an inclined surface 170s of the second device isolation pattern 170 and the first surface 100a of the substrate 100.

The inclined surface 170s of the second device isolation pattern 170 may overlap with the transfer gate TG. The material composition of the second device isolation pattern 170 may differ from that of the first device isolation pattern 130. In one or more embodiments, the first device isolation pattern 130 may include SiO and SiN, and the second device isolation pattern 170 may include SiN but not SiO. However, the present disclosure is not limited thereto, and alternatively, the second device isolation pattern 170 may include SiCN or SiOCN.

In this manner, the second device isolation pattern 170, due to its positive fixed charge property, can control unexpected electrons generated in adjacent transfer gates TG during processing. That is, the second device isolation pattern 170 can prevent noise caused by dark current within each unit pixel region PX. Therefore, an image sensor with improved reliability can be provided.

Furthermore, as will be described later, the second device isolation pattern 170 may be formed via a different process from the first device isolation pattern 130, thereby enhancing the design flexibility of the image sensor according to one or more embodiments.

The first and second device isolation patterns 130 and 170 may divide the active regions within the first through fourth unit pixel regions PX1 through PX4 into first active regions A1 through A4, respectively, and second active regions B1 through B4, respectively.

For example, the first and second device isolation patterns 130 and 170 may divide the active region in the first unit pixel region PX1 into the first and second active regions A1 and B1, the active region in the second unit pixel region PX2 into the first and second active regions A2 and B2, the active region in the third unit pixel region PX3 into the first and second active regions A3 and B3, and the active region in the fourth unit pixel region PX4 into the first and second active regions A4 and B4.

In one or more embodiments, the first active regions A1 through A4 and the second active regions B1 through B4 within the first through fourth unit pixel regions PX1 through PX4 may have rounded edges from a planar perspective.

The first through fourth unit pixel regions PX1 through PX4 may include the second active regions B1, B2, B3, and B4, respectively, defined by the first and second device isolation patterns 130 and 170. From a planar perspective, the second active regions B1, B2, B3, and B4 may be located in the edge regions of the respective unit pixel regions PX.

In one or more embodiments, the second active regions B1, B2, B3, and B4 within the first through fourth unit pixel regions PX1 through PX4 may include ground regions GND connected to the ground. The ground regions GND may be doped regions. For example, the ground regions GND may have the second conductivity type (e.g., n-type). By defining the second active region B1 with the second device isolation pattern 170 having a narrow width, the area of the second active region B1 in the first unit pixel region PX1 may be maximized. For example, the area of the ground region GND included in the second active region B1 may be maximized. Through this, an image sensor with improved reliability can be provided.

However, the planar shapes of the first active regions A1, A2, A3, and A4 and the second active regions B1, B2, B3, and B4 are not limited to those illustrated in FIG. 4 and may vary.

Transfer transistors TX, source follower transistors SX, reset transistors RX, and selection transistors AX, described with reference to FIG. 1, may be provided on the first surface 100a of the substrate 100. The transfer transistors TX may be provided on the first active regions A1, A2, A3, and A4 of the first through fourth unit pixel regions PX1 through PX4. The transfer transistors TX may be electrically connected to the photoelectric conversion regions 110. The transfer transistors TX may include, on the first active regions A1, A2, A3, and A4, transfer gates TG and floating diffusion regions FD.

The transfer transistors TX may include transfer gates TG and floating diffusion regions FD. The floating diffusion regions FD may be adjacent to the first surface 100a of the substrate 100. The floating diffusion regions FD may be provided in the upper portion of the substrate 100.

A gate insulating film GI may be positioned between the transfer gates TG and the substrate 100.

The floating diffusion regions FD may be adjacent to first sides of the transfer gates TG. The floating diffusion regions FD may be located within the first active regions A1, A2, A3, and A4. The floating diffusion regions FD may have the second conductivity type (e.g., n-type) opposite to that of the substrate 100.

The gate electrodes (TG, SEL, SF, RG, and DCG) may be provided on the first surface 100a of the substrate 100. The gate electrodes (TG, SEL, SF, RG, and DCG) may include transfer gates TG, selection gates SEL, source follower gates SF, reset gates RG, and dual conversion gates DCG.

The first wiring layer 20 may include first through fourth insulating layers 221 through 224, wirings (212 and 213), vias 215, and contacts CT. The first insulating layer 221 may cover the first surface 100a of the substrate 100. The second insulating layer 222 may be provided on the first insulating layer 221. The first and second insulating layers 221 and 222 may be provided between the wirings (212 and 213) and the first surface 100a of the substrate 100, covering the gate electrodes (TG, SEL, SF, RG, and DCG). The third insulating layer 223 may be provided on the second insulating layer 222, and the fourth insulating layer 224 may be provided on the third insulating layer 223. The first through fourth insulating layers 221 through 224 may include a non-conductive material. For example, the first through fourth insulating layers 221 through 224 may include an Si-based insulating material such as SiO, silicon nitride, or silicon oxynitride.

The wirings (212 and 213) may be provided on the second insulating layer 222. The wirings (212 and 213) may be vertically connected to the transfer transistors TX, source follower transistors SX, reset transistors RX, dual conversion transistors DCX, and selection transistors AX through the contacts CT. The wirings (212 and 213) may also be vertically connected to the floating diffusion regions FD through the contacts CT. The contacts CT may penetrate the first and second insulating layers 221 and 222. Contacts corresponding to the gate electrodes (TG, SEL, SF, RG, DCG) may penetrate gate spacers GS. Electrical signals converted in the photoelectric conversion regions 110 may be processed in the first wiring layer 20. The arrangement of the wirings (212 and 213) may vary and is not limited to that illustrated, regardless of the arrangement of the photoelectric conversion regions 110. The wirings (212 and 213) may include first wirings 212 and second wirings 213. The first wirings 212 may be provided in the third insulating layer 223, and the second wirings 213 may be provided in the fourth insulating layer 224. The vias 215 may be provided in the third and fourth insulating layers 223 and 224. The vias 215 may electrically connect the first wirings 212 and the second wirings 213. The first wirings 212 and the second wirings 213, the vias 215, and the contacts CT may include a metallic material. For example, the first wirings 212 and the second wirings 213, the vias 215, and the contacts CT may include copper (Cu).

The light-transmitting layer 30 may include color filters 303 and microlenses 307. The light-transmitting layer 30 may collect and filter external incident light and deliver it to the photoelectric conversion layer 10.

Specifically, the color filters 303 and the microlenses 307 may be provided on the second surface 100b of the substrate 100. The color filters 303 may be individually arranged on the unit pixel regions PX. The microlenses 307 may be individually arranged on the color filters 303. An anti-reflective film 132 and first and second insulating films 134 and 136 may be disposed between the second surface 100b of the substrate 100 and the color filters 303. The anti-reflective film 132 may prevent reflection of light, ensuring smooth transmission of the light to the photoelectric conversion regions 110. A third insulating film 305 may be disposed between the color filters 303 and the microlenses 307.

The color filters 303 may include primary color filters. The color filters 303 may include first, second, and third color filters of different colors. For example, the first, second, and third color filters may include green, red, and blue color filters. The first, second, and third color filters may be arranged in a Bayer pattern. Alternatively, the first, second, and third color filters may include other colors, such as cyan, magenta, or yellow.

The microlenses 307 may have a convex shape to collect light incident on the unit pixel regions PX. From a planar perspective, the microlenses 307 may overlap with the photoelectric conversion regions 110.

FIG. 5 corresponds to the drawing related to FIG. 4, and for convenience of explanation, differences from FIG. 4 will be mainly described. Referring to FIG. 5, in some embodiments, the active regions (A1 to A4, B1 to B4) separated by the first device isolation pattern (130) and the second device isolation pattern (170) may have chamfered corners. For example, the corners of the active regions (A1 to A4, B1 to B4) may be in a rounded shape. By separating the active regions using the second device isolation pattern (170), it is possible to prevent pattern shortening and thereby increase the margin where the active region overlaps with a contact (not shown).

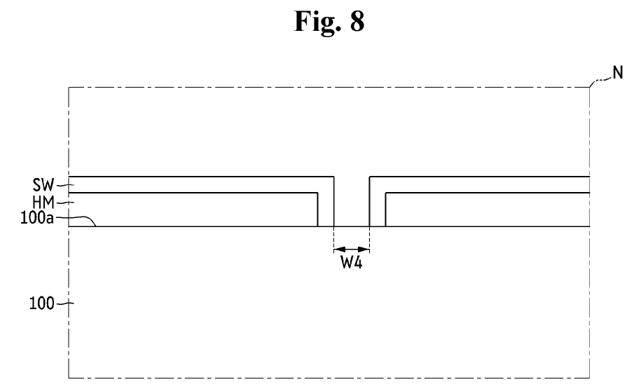

FIGS. 8 through 18 are enlarged views of region N of FIG. 6, illustrating a method of manufacturing an image sensor according to one or more embodiments.

Referring to FIGS. 7 and 8, a substrate 100 may have a first surface 100a and a second surface 100b, which are opposite to each other. Light may be incident on the second surface 100b of the substrate 100. The substrate 100 may include impurities of a first conductivity type.

A hard mask pattern HM and an insulating film SW may be formed on the first surface 100a of the substrate 100. The hard mask pattern HM and the insulating film SW illustrated in FIG. 8 may be used to form a second shallow trench ST2. The hard mask pattern HM may be formed to partially expose the first surface 100a of the substrate 100.

The width of the exposed portion of the first surface 100a of the substrate 100 may correspond to a fourth width W4. The insulating film SW may be formed on the hard mask pattern HM through an atomic layer deposition (ALD) process. For example, the insulating film SW may include at least one of silicon oxide, silicon nitride, boron-phosphosilicate glass (BPSG), or borosilicate glass (BSG).

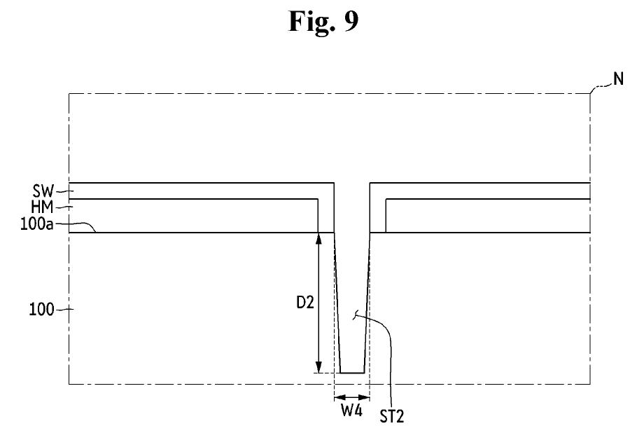

Referring to FIGS. 7 and 9, the second shallow trench ST2 may be formed using the hard mask pattern HM and the insulating film SW formed on the first surface 100a of the substrate 100. The width of the second shallow trench ST2 may correspond to the fourth width W4, and the depth of the second shallow trench ST2 may correspond to a second depth D2. By forming an additional insulating film SW on the hard mask pattern HM, a narrower trench than a first shallow trench ST1, whose fabrication method will be described later, may be formed. In this manner, the area of active regions (e.g., B2) within each unit pixel region PX can be maximized, thereby providing an image sensor with improved reliability.

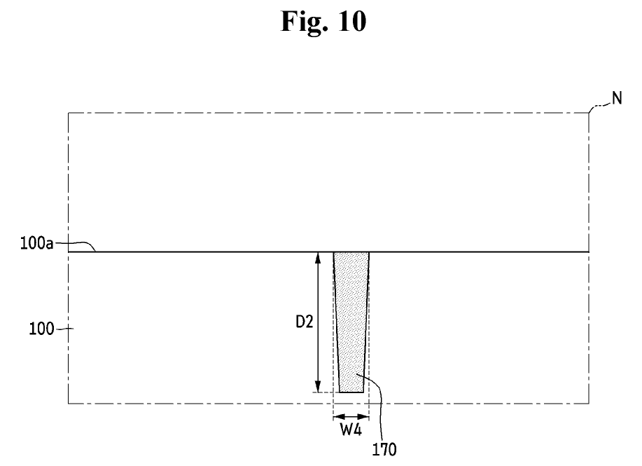

Referring to FIGS. 7 and 10, the hard mask pattern HM and the insulating film SW formed on the first surface 100a of the substrate 100 may be removed, and a second device isolation pattern 170 may be formed within the second shallow trench ST2. The width of the second device isolation pattern 170 may decrease away from the first surface 100a of the substrate 100. The width of the second device isolation pattern 170 may correspond to the fourth width W4, and the depth of the second device isolation pattern 170 may correspond to the second depth D2.

The second device isolation pattern 170 may include an insulating material. In one or more embodiments, the second device isolation pattern 170 may include silicon nitride.

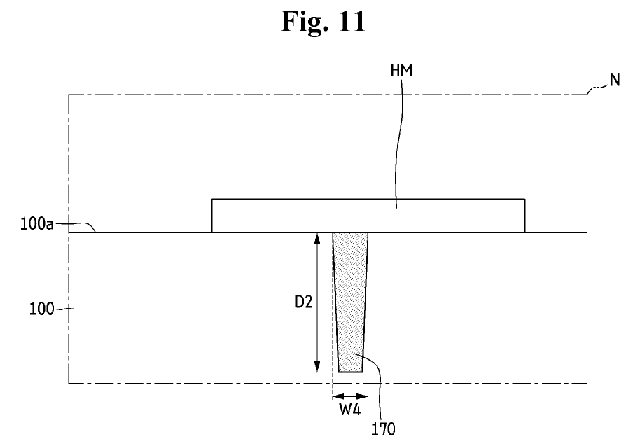

Referring to FIGS. 7 and 11, a hard mask pattern HM may be formed on the first surface 100a of the substrate 100 and the second device isolation pattern 170. The hard mask pattern HM in FIG. 11 may be used to form the first shallow trench ST1. The hard mask pattern HM may be formed to partially expose the first surface 100a of the substrate 100.

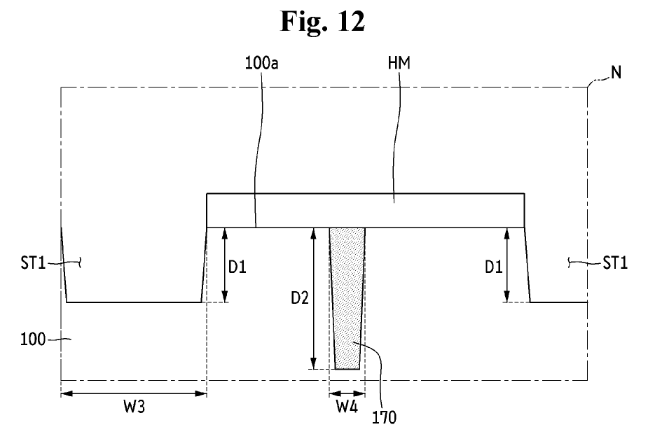

Referring to FIGS. 7 and 12, the first shallow trench ST1 may be formed using the hard mask pattern HM formed on the first surface 100a of the substrate 100 and the second device isolation pattern 170. The width of the first shallow trench ST1 may correspond to a third width W3, and the depth of the first shallow trench ST1 may correspond to a first depth D1.

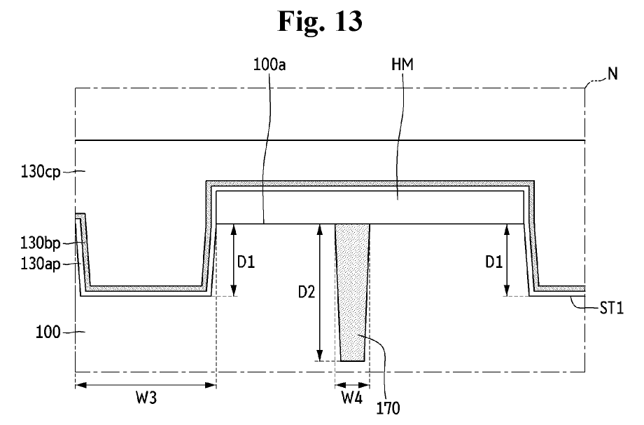

Referring to FIGS. 7 and 13, preliminary device isolation patterns 130ap, 130bp, and 130cp may be formed on the first surface 100a of the substrate 100. The preliminary device isolation patterns 130ap, 130bp, and 130cp may be formed through a deposition process performed on the first surface 100a of the substrate 100. The preliminary device isolation patterns 130ap, 130bp, and 130cp may fully fill the first shallow trench ST1 and cover the hard mask pattern HM. The upper surfaces of the preliminary device isolation patterns 130ap, 130bp, and 130cp may be at a higher level than the first surface 100a of the substrate 100.

The preliminary device isolation patterns 130ap, 130bp, and 130cp may include, for example, silicon oxide, silicon nitride, and/or silicon oxynitride.

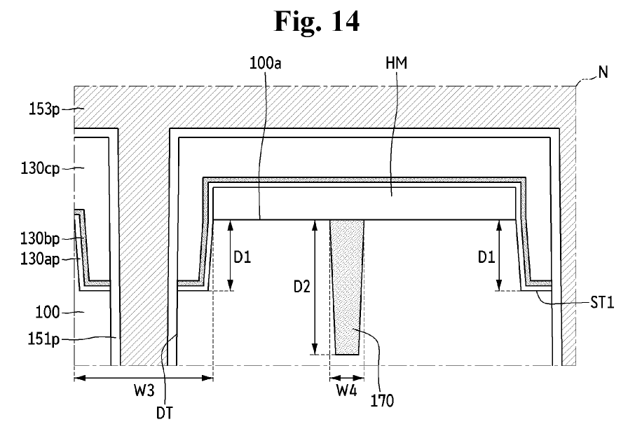

Referring to FIGS. 7 and 14, a deep trench DT may be formed by anisotropically etching the preliminary device isolation patterns 130ap, 130bp, and 130cp and the substrate 100.

After the formation of the deep trench DT, a first preliminary isolation pattern 151p conformally covering the inner sidewalls of the deep trench DT may cover the inner walls of the deep trench DT and the upper surfaces of the preliminary device isolation patterns 130ap, 130bp, and 130cp. The first preliminary isolation pattern 151p may be formed by depositing an insulating material on the substrate 100 in which the deep trench DT is formed. For example, the first preliminary isolation pattern 151p may include silicon oxide, silicon nitride, and/or silicon oxynitride.

A second preliminary isolation pattern 153p may be formed on the first preliminary isolation pattern 151p. The second preliminary isolation pattern 153p may be formed through a deposition process on the substrate 100 in which the first preliminary isolation pattern 151p is formed. The second preliminary isolation pattern 153p may cover the first preliminary isolation pattern 151p on the inner sidewalls of the deep trench DT and the upper surfaces of the preliminary device isolation patterns 130ap, 130bp, and 130cp. For example, the second preliminary isolation pattern 153p may include polysilicon.

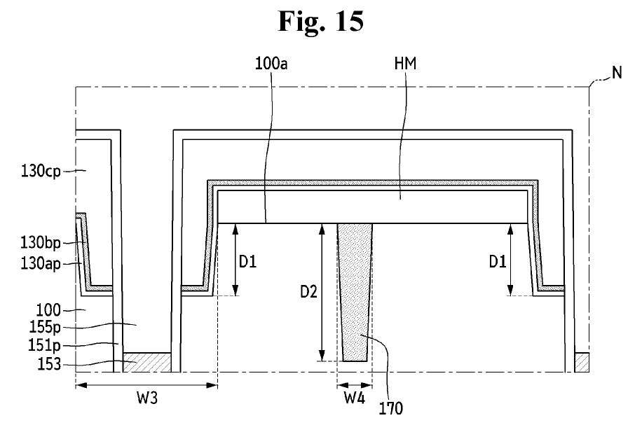

Referring to FIGS. 7 and 15, an upper portion of the second preliminary isolation pattern 153p may be removed to form the second isolation pattern 153. As a result, part of the first preliminary isolation pattern 151p may be exposed. The upper surface of the second isolation pattern 153 may be positioned at a lower level than the lower surface of the preliminary device isolation pattern 130ap.

A doping process may be performed on the second isolation pattern 153. The doping process may be, for example, a beam-line ion implantation process or a plasma doping (PLAD) process.

A preliminary capping pattern 155p, covering the entire surface of the substrate 100 and filling the upper portion of a first trench TR1, may be formed. Forming the preliminary capping pattern 155p may include performing a deposition process on the first surface 100a of the substrate 100. The preliminary capping pattern 155p may include silicon oxide, silicon nitride, and/or silicon oxynitride.

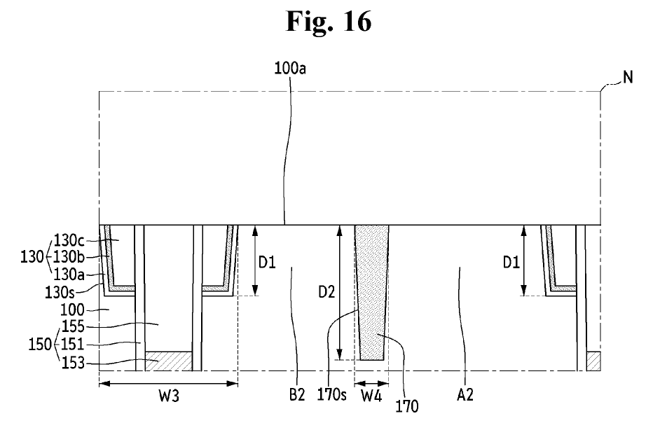

Referring to FIGS. 7 and 16, a capping pattern 155 and a first device isolation pattern 130 may be formed. Forming the capping pattern 155 and the first device isolation pattern 130 may include performing a planarization process on the first surface 100a of the substrate 100. Upon the completion of the planarization process, first active regions A1, A2, A3, and A4 and second active regions B1, B2, B3, and B4 may be formed, as described with reference to FIG. 4.

The width of the first device isolation pattern 130 may be greater than the width of the second device isolation pattern 170. In this specification, the term “width” may refer to the length in the direction in which the active regions are spaced apart or separated by the first device isolation pattern 130 or the second device isolation pattern 170. The term “width” may also refer to the length measured on the first surface 100a of the substrate 100. In one or more embodiments, the first device isolation pattern 130 may have a third width W3, and the second device isolation pattern 170 may have a fourth width W4. The third width W3 may be greater than the fourth width W4. Through this, the areas of the first and second active regions (e.g., A2 and B2) within each unit pixel region PX can be maximized.

The depth of the first device isolation pattern 130 may be less than the depth of the second device isolation pattern 170. In one or more embodiments, the first device isolation pattern 130 may have a first depth D1, and the second device isolation pattern 170 may have a second depth D2. The first depth D1 may be less than the second depth D2.

In one or more embodiments, the angle formed between the inclined surface 130s of the first device isolation pattern 130 and the first surface 100a of the substrate 100 may be smaller than the angle formed between the inclined surface 170s of the second device isolation pattern 170 and the first surface 100a of the substrate 100.

The first device and second device isolation patterns 130 and 170 may be formed of different materials. In one or more embodiments, the first device isolation pattern 130 may include SiO and SiN, and the second device isolation pattern 170 may include SiN but not SiO. Through this, the second device isolation pattern 170 can prevent noise within each unit pixel region PX. Accordingly, an image sensor with improved reliability can be provided.

Additionally, the second device isolation pattern 170 may be formed through a different process from the first device isolation pattern 130, thereby enhancing the design flexibility of the image sensor.

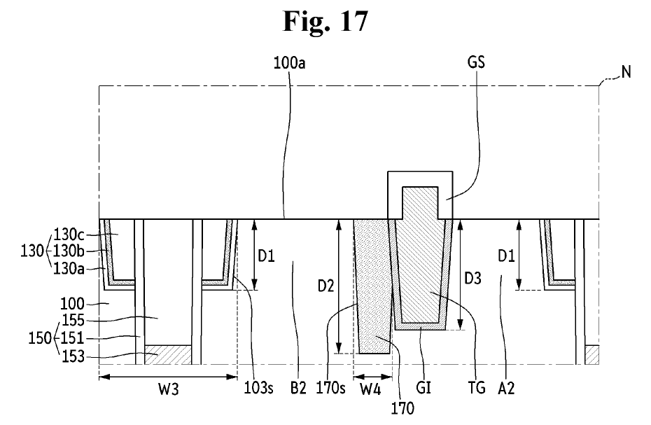

Referring to FIG. 17, a transfer gate TG may be formed on the first active region A2 within the second unit pixel region PX2. The transfer gate TG may be adjacent to one side of the second device isolation pattern 170.

A gate insulating film GI may be disposed between the substrate 100 and the transfer gate TG. A gate spacer GS may be formed on the transfer gate TG. For example, the gate spacer GS may include silicon nitride, silicon carbonitride, or silicon oxynitride.

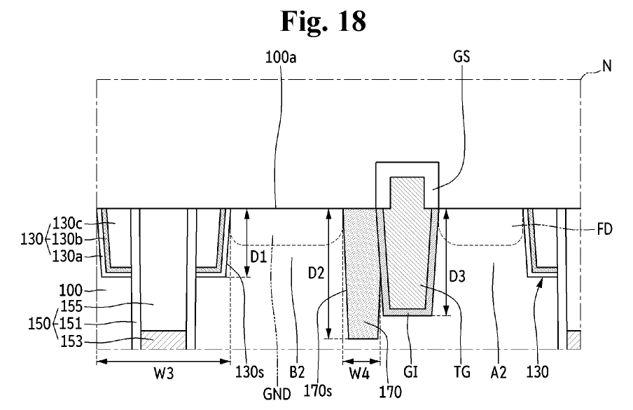

Referring to FIGS. 7 and 18, impurities may be implanted into the first surface 100a of the substrate 100 to form a ground region GND and a floating diffusion region FD. The impurities may function as a dopant within the ground region GND and the floating diffusion region FD. The ground region GND and the floating diffusion region FD may include impurities of a second conductivity type (e.g., n-type). The floating diffusion region FD may be formed within the first active region A2, and the ground region GND may be formed within the second active region B2.

Referring back to FIG. 6, a first wiring layer 20 may be formed on the first surface 100a of the substrate 100. Contacts CT penetrating first and second insulating layers 221 and 222 may be formed. The contacts CT may be connected to at least one of the ground region GND, gate electrodes (TG, SEL, SF, RG, and DCG), or the floating diffusion region FD. Contacts CT corresponding to the gate electrodes (TG, SEL, SF, RG, DCG) may penetrate gate spacers GS. First wirings 212 may be formed on the upper surface of the second insulating layer 222. A third insulating layer 223 may be formed on the second insulating layer 222. The third insulating layer 223 may cover the upper surfaces and sidewalls of the first wirings 212. Vias 215 penetrating the third insulating layer 223 may be formed. The vias 215 may electrically connect second wirings 213, which will be described later, to the first wirings 212. The second wirings 213 may be formed on the third insulating layer 223. A fourth insulating layer 224 may be formed on the third insulating layer 223. The fourth insulating layer 224 may cover the upper surfaces and sidewalls of the second wirings 213. Vias 215 penetrating the fourth insulating layer 224 may be formed.

An anti-reflective film 132, a first insulating film 134, and a second insulating film 136 may be sequentially formed on the second surface 100b of the substrate 100. Color filters 303 may be formed on the unit pixel regions PX. A third insulating film 305 may be formed on the color filters 303. Microlenses 307 may be formed on the third insulating film 305 to overlap with the unit pixel regions PX.

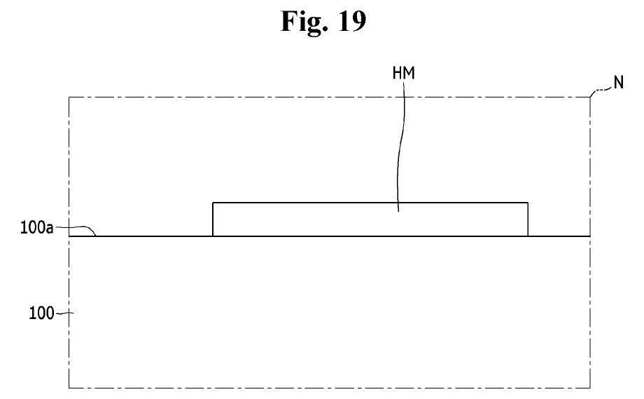

FIGS. 19 through 23 are enlarged views of region N of FIG. 6, illustrating a method of manufacturing an image sensor according to one or more embodiments.

Referring to FIGS. 7 and 19, a hard mask pattern HM may be formed on a first surface 100a of a substrate 100. The hard mask pattern HM illustrated in FIG. 19 may be used to form a first shallow trench ST1. The hard mask pattern HM may be formed to partially expose the first surface 100a of the substrate 100.

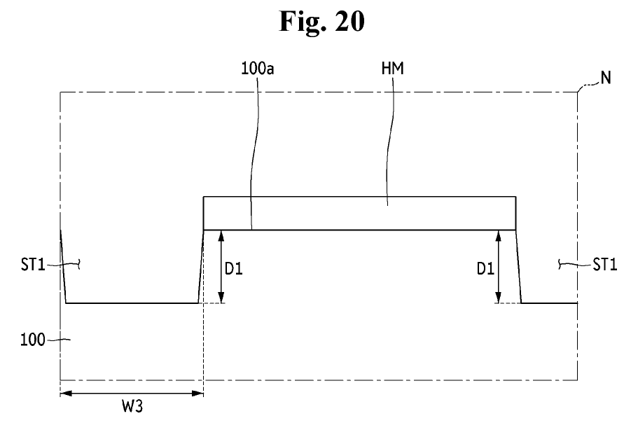

Referring to FIGS. 7 and 20, the first shallow trench ST1 may be formed using the hard mask pattern HM formed on the first surface 100a of the substrate 100. The width of the first shallow trench ST1 may correspond to a third width W3, and the depth of the first shallow trench ST1 may correspond to a first depth D1.

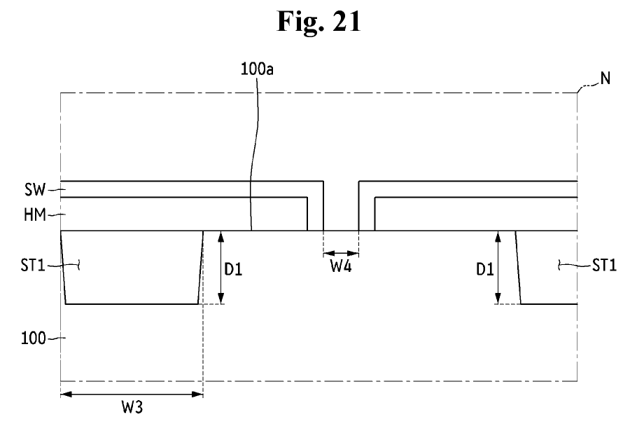

Referring to FIGS. 7 and 21, a hard mask pattern HM and an insulating film SW may be formed on the first surface 100a of the substrate 100 and the first shallow trench ST1. The hard mask pattern HM and the insulating film SW illustrated in FIG. 21 may be used to form a second shallow trench ST2. The hard mask pattern HM may be formed to partially expose the first surface 100a of the substrate 100.

The width of the exposed portion of the first surface 100a of the substrate 100 may correspond to a fourth width W4. The insulating film SW may be formed on the hard mask pattern HM through an ALD process. For example, the insulating film SW may include at least one of silicon oxide, silicon nitride, BPSG, or BSG.

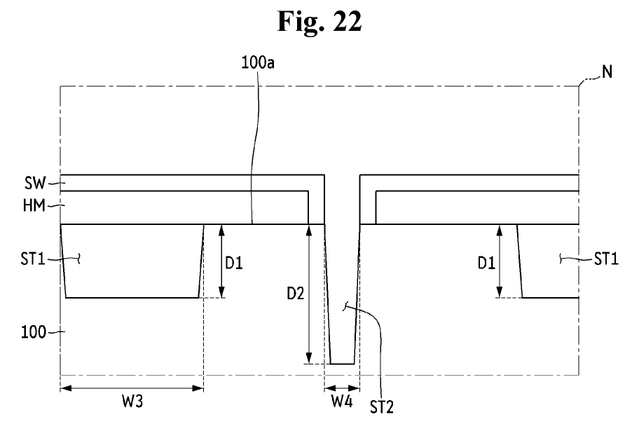

Referring to FIGS. 7 and 22, the second shallow trench ST2 may be formed using the hard mask pattern HM and the insulating film SW formed on the first surface 100a of the substrate 100 and a first device isolation pattern 130. The width of the second shallow trench ST2 may correspond to the fourth width W4, and the depth of the second shallow trench ST2 may correspond to a second depth D2. By forming an additional insulating film SW on the hard mask pattern HM, a narrower second shallow trench ST2 may be formed compared to the first shallow trench ST1, which is formed solely by the hard mask pattern HM. In this manner, the area of the active regions within each unit pixel region PX can be maximized, thereby providing an image sensor with improved reliability.

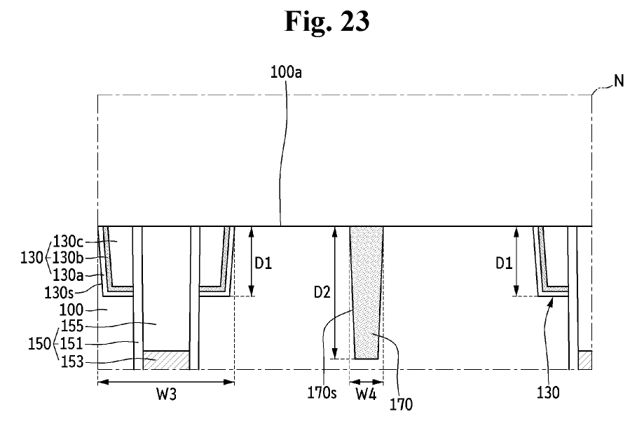

Referring to FIGS. 7 and 23, the hard mask pattern HM and the insulating film SW formed on the first surface 100a of the substrate 100 may be removed, and a first device isolation pattern 130 may be formed within the first shallow trench ST1. The first device isolation pattern 130 may include a second liner layer 130b and a gap-fill layer 130c, which may include different materials.

The second liner layer 130b may be disposed within the first shallow trench ST1. The second liner layer 130b may be disposed on the sidewalls and the lower surface of the first shallow trench ST1. The second liner layer 130b may extend along the sidewalls and the lower surface of the first shallow trench ST1.

The second liner layer 130b may include an insulating material. In one or more embodiments, the second liner layer 130b may include SiN, SiCN, or SiOCN.

The gap-fill layer 130c may be disposed on the second liner layer 130b. In one or more embodiments, the gap-fill layer 130c may include SiO.

A second device isolation pattern 170 may be formed within the second shallow trench ST2. The width of the second device isolation pattern 170 may gradually decrease away from the first surface 100a of the substrate 100. The width of the second device isolation pattern 170 may correspond to the fourth width W4, and the depth of the second device isolation pattern 170 may correspond to the second depth D2.

The second device isolation pattern 170 may include an insulating material. In one or more embodiments, the second device isolation pattern 170 may include silicon nitride.

In one or more embodiments, the first device isolation pattern 130 may have the third width W3, and the second device isolation pattern 170 may have the fourth width W4. The third width W3 may be greater than the fourth width W4. Through this, the area of the active regions within each unit pixel region PX can be maximized.

A separation pattern 150 may be formed to penetrate the first device isolation pattern 130. The process for forming the first device isolation pattern 130 may be similar to that described with reference to FIGS. 13 through 16, and thus, a detailed explanation thereof will be omitted.

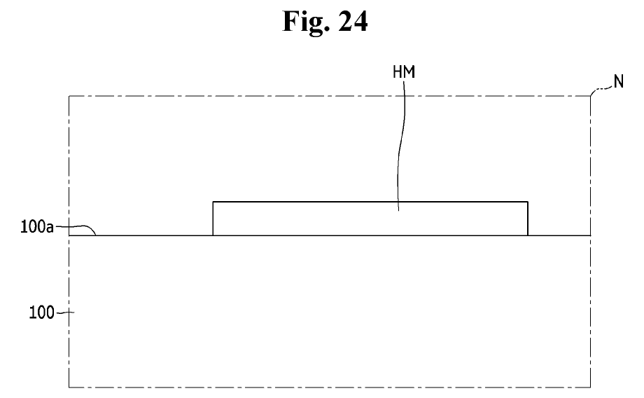

FIGS. 24 through 29 are enlarged views of region N of FIG. 6, illustrating a method of manufacturing an image sensor according to one or more embodiments.

Referring to FIGS. 7 and 24, a hard mask pattern HM may be formed on a first surface 100a of a substrate 100. The hard mask pattern HM illustrated in FIG. 24 may be used to form a first shallow trench ST1. The hard mask pattern HM may be formed to partially expose the first surface 100a of the substrate 100.

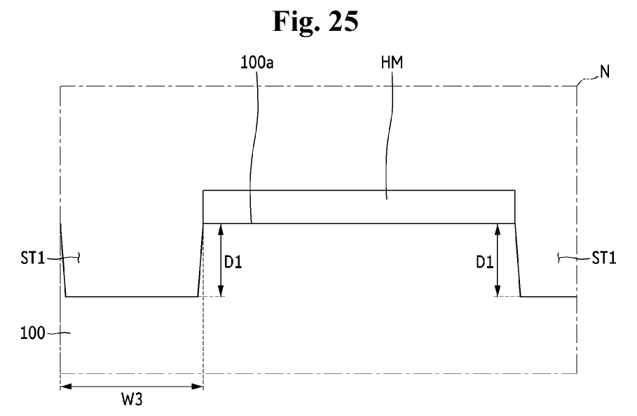

Referring to FIGS. 7 and 25, the first shallow trench ST1 may be formed using the hard mask pattern HM formed on the first surface 100a of the substrate 100. The width of the first shallow trench ST1 may correspond to a third width W3, and the depth of the first shallow trench ST1 may correspond to a first depth D1.

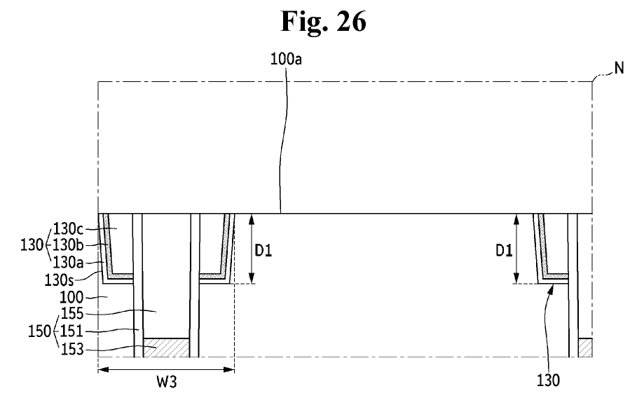

Referring to FIGS. 7 and 26, a separation pattern 150 and a first device isolation pattern 130 may be formed. The process for forming the separation pattern 150 and the first device isolation pattern 130 is similar to that described with reference to FIGS. 13 through 16, and thus, a detailed explanation thereof will be omitted.

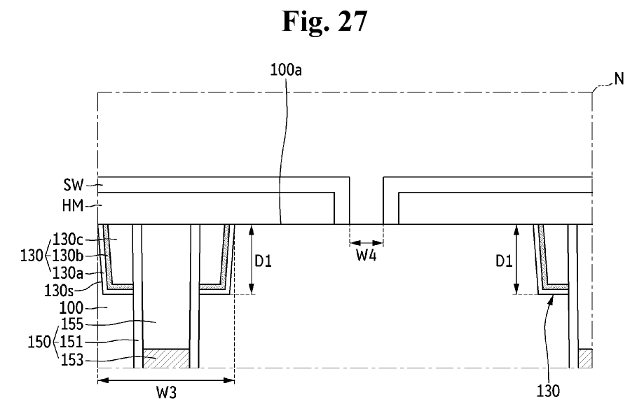

Referring to FIGS. 7 and 27, a hard mask pattern HM and an insulating film SW may be formed on the first surface 100a of the substrate 100, the separation pattern 150, and the first device isolation pattern 130. The hard mask pattern HM and the insulating film SW illustrated in FIG. 27 may be used to form a second shallow trench ST2. The hard mask pattern HM may be formed to partially expose the first surface 100a of the substrate 100.

The width of the exposed portion of the first surface 100a of the substrate 100 may correspond to a fourth width W4. The insulating film SW may be formed on the hard mask pattern HM through an ALD process. For example, the insulating film SW may include at least one of silicon oxide, silicon nitride, BPSG, or BSG.

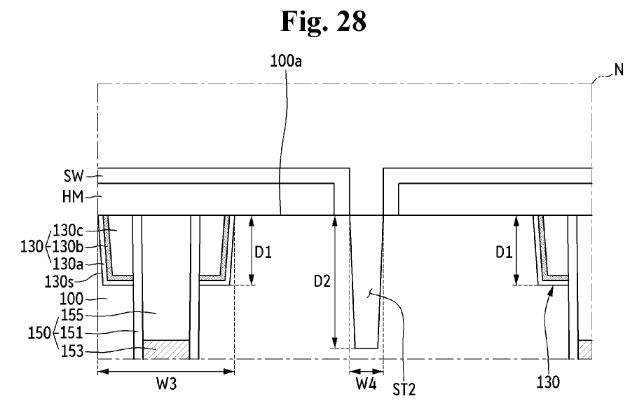

Referring to FIGS. 7 and 28, the second shallow trench ST2 may be formed using the hard mask pattern HM and the insulating film SW formed on the first surface 100a of the substrate 100, the separation pattern 150, and the first device isolation pattern 130. The width of the second shallow trench ST2 may correspond to the fourth width W4, and the depth of the second shallow trench ST2 may correspond to a second depth D2. By forming an additional insulating film SW on the hard mask pattern HM, a narrower second shallow trench ST2 may be formed compared to the first shallow trench ST1, which is formed solely by the hard mask pattern HM. In this manner, the area of the active regions within each unit pixel region PX can be maximized.

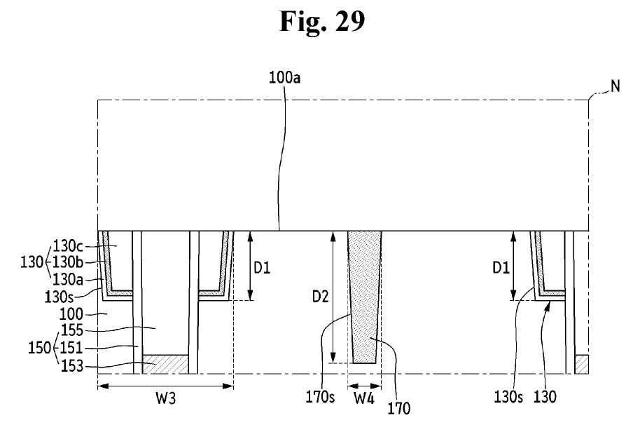

Referring to FIGS. 7 and 29, the hard mask pattern HM and the insulating film SW formed on the first surface 100a of the substrate 100 may be removed, and a second device isolation pattern 170 may be formed within the second shallow trench ST2. The width of the second device isolation pattern 170 may decrease away from the first surface 100a of the substrate 100. The width of the second device isolation pattern 170 may correspond to the fourth width W4, and the depth of the second device isolation pattern 170 may correspond to the second depth D2.

In one or more embodiments, the first device isolation pattern 130 may have the third width W3, and the second device isolation pattern 170 may have the fourth width W4. The third width W3 may be greater than the fourth width W4. Through this, the area of the active regions within each unit pixel region PX can be maximized.

The second device isolation pattern 170 may include an insulating material. In one or more embodiments, the second device isolation pattern 170 may include silicon nitride.

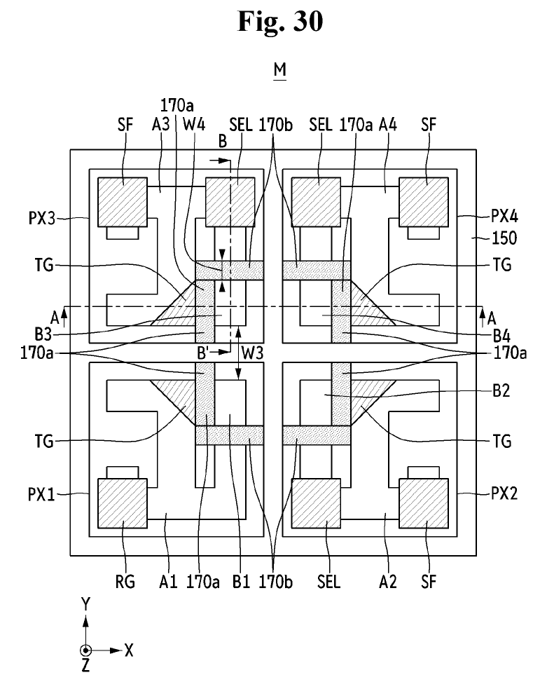

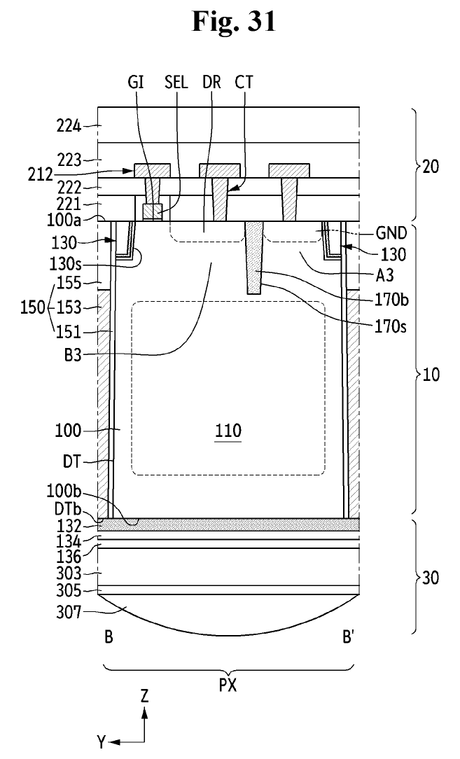

FIG. 30 is an enlarged view of region M of FIG. 2. FIG. 31 is a cross-sectional view taken along line B-B’ of FIG. 30. FIGS. 30 and 31 present similar configurations to those described with reference to FIGS. 4 and 6, and thus, descriptions of the configurations described with reference to FIGS. 4 and 6 will be omitted.

Referring to FIGS. 6, 30, and 31, an image sensor according to one or more embodiments may include a photoelectric conversion layer 10, gate electrodes (TG, RG, SEL, and SF), a first wiring layer 20, and a light-transmitting layer 30. The photoelectric conversion layer 10 may include a substrate 100, a separation pattern 150, a first device isolation pattern 130, and a second device isolation pattern 170.

The substrate 100 may include a plurality of first through fourth unit pixel regions PX1 through PX4 defined by the separation pattern 150.

In one or more embodiments, the separation pattern 150 may be provided within the substrate 100 and may define the first through fourth unit pixel regions PX1 through PX4. For example, the separation pattern 150 may be provided between the first through fourth unit pixel regions PX1 through PX4 of the substrate 100. The separation pattern 150 may separate the first through fourth unit pixel regions PX1 through PX4 from one another.

The separation pattern 150 may be provided within a deep trench DT. The separation pattern 150 may penetrate the first device isolation pattern 130. At least a portion of the first device isolation pattern 130 may contact the upper sidewalls of the separation pattern 150. The sidewalls and lower surface of the first device isolation pattern 130 and the sidewalls of the separation pattern 150 may have a stepped structure. The depth of the first device isolation pattern 130 may be less than the depth of the separation pattern 150.

The separation pattern 150 may include a first isolation pattern 151, a second isolation pattern 153, and a capping pattern 155.

The first device isolation pattern 130 may be provided within the substrate 100. For example, the first device isolation pattern 130 may be provided within a first shallow trench ST1.

The first device isolation pattern 130 may include a first liner layer 130a, a second liner layer 130b, and a gap-fill layer 130c, which may include different materials.

The first liner layer 130a may include an insulating material. In one or more embodiments, the first liner layer 130a may include SiO.

The second liner layer 130b may include an insulating material. In one or more embodiments, the second liner layer 130b may include SiN, SiCN, or SiOCN.

The gap-fill layer 130c may be disposed on the second liner layer 130b. In one or more embodiments, the gap-fill layer 130c may include SiO.

The second device isolation pattern 170 may be provided within the substrate 100. For example, the second device isolation pattern 170 may be provided within a second shallow trench ST2.

The second device isolation pattern 170 may include an insulating material. In one or more embodiments, the second device isolation pattern 170 may include silicon nitride.

The width of the first device isolation pattern 130 may be greater than the width of the second device isolation pattern 170. In this specification, the term “width” may refer to the length in the direction in which active regions are spaced apart or separated by the first device isolation pattern 130 or the second device isolation pattern 170. The term “width” may also refer to the length measured on a first surface 100a of the substrate 100.

In one or more embodiments, the first device isolation pattern 130 may have a third width W3, and the second device isolation pattern 170 may have a fourth width W4. The minimum value of the third width W3 may be greater than the minimum value of the fourth width W4. For example, the third width W3 may range from 40 nm to 60 nm, and the fourth width W4 may range from 20 nm to 40 nm. Through this, the area of the active regions within each unit pixel region PX can be maximized.

The depth of the first device isolation pattern 130 may be less than the depth of the second device isolation pattern 170. In one or more embodiments, the first device isolation pattern 130 may have a first depth D1, and the second device isolation pattern 170 may have a second depth D2. The first depth D1 may be less than the second depth D2. For example, the first depth D1 may range from 250 nm to 350 nm, and the second depth D2 may be greater than 250 nm to 350 nm.

The first device isolation pattern 130 and the second device isolation pattern 170 may include different materials. In one or more embodiments, the first device isolation pattern 130 may include SiO and SiN, and the second device isolation pattern 170 may include SiN but not SiO. However, the present disclosure is not limited to this, and alternatively, the second device isolation pattern 170 may include SiCN or SiOCN.

The first and second device isolation patterns 130 and 170 may divide the active regions within the first through fourth unit pixel regions PX1 through PX4 into first active regions A1, A2, A3, and A4, respectively, and second active regions B1, B2, B3, and B4, respectively. The second device isolation pattern 170 may include a first auxiliary device isolation pattern 170a and a second auxiliary device isolation pattern 170b.

For example, the first and second auxiliary device isolation patterns 170a and 170b may separate the second active region B1 from the active region in the first unit pixel region PX1, the second active region B2 from the active region in the second unit pixel region PX2, the second active region B3 from the active region in the third unit pixel region PX3, and the second active region B4 from the active region in the fourth unit pixel region PX4. In one or more embodiments, the first active regions A1 through A4 and the second active regions B1 through B4 within the respective unit pixel regions PX may have rounded edges from a planar perspective.

From a planar perspective, the second active regions B1, B2, B3, and B4 may be located in the edge regions of the respective unit pixel regions PX.

In one or more embodiments, the second active regions B1, B2, B3, and B4 within the respective unit pixel regions PX may include ground regions GND connected to the ground. The ground regions GND may be doped regions. For example, the ground regions GND may have a second conductivity type (e.g., n-type). By defining the second active region B3 using the first and second auxiliary device isolation patterns 170a and 170b with a narrow width, the area of the second active region B1 within the first unit pixel region PX1 can be maximized. For example, the area of the ground region GND included in the second active region B3 can be maximized. Through this, an image sensor with improved reliability can be provided.

Selection transistors AX may include selection gates SEL and impurity regions DR. The impurity region DR may be adjacent to the first surface 100a of the substrate 100. Floating diffusion regions FD may be provided in the upper portion of the substrate 100.

However, the planar shapes of the first active regions A1, A2, A3, and A4 and the second active regions B1, B2, B3, and B4 are not limited to those illustrated in FIG. 30 and may vary.

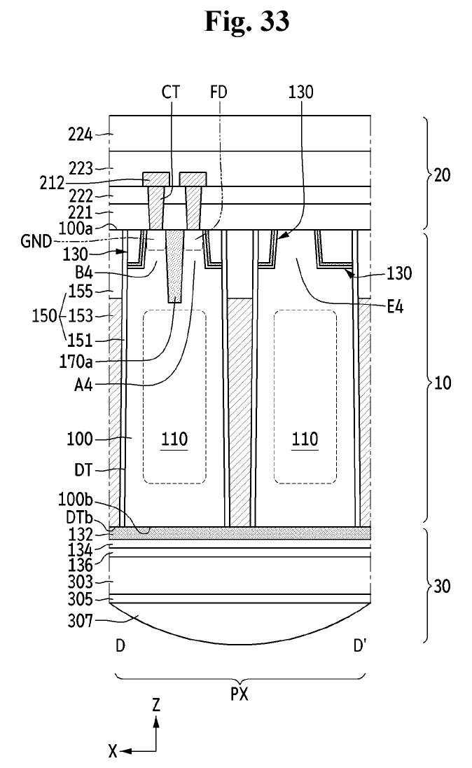

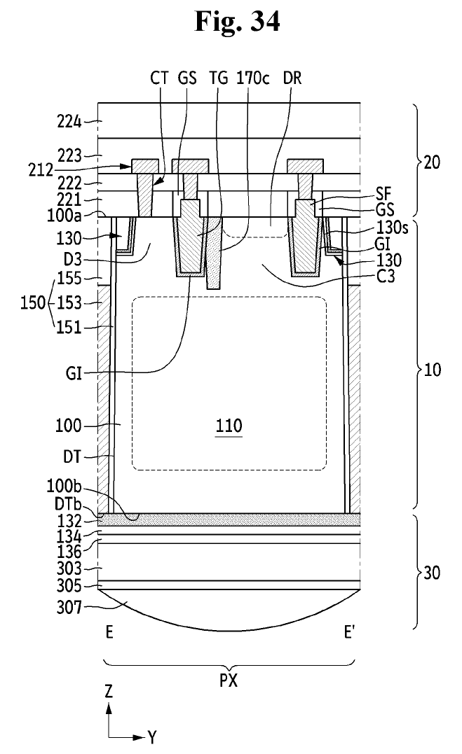

FIG. 32 is an enlarged view of region M of FIG. 2. FIG. 33 is a cross-sectional view taken along line D-D’ of FIG. 32, and FIG. 34 is a cross-sectional view taken along line E-E’ of FIG. 32.

Referring to FIGS. 32 through 34, an image sensor according to one or more embodiments may include a photoelectric conversion layer 10, gate electrodes (TG, RG, SEL, DCG, and SF), a first wiring layer 20, and a light-transmitting layer 30. The photoelectric conversion layer 10 may include a substrate 100, a separation pattern 150, a first device isolation pattern 130, and a second device isolation pattern 170.

The substrate 100 may include a plurality of first through fourth unit pixel regions PX1 through PX4 defined by the separation pattern 150.

In one or more embodiments, the separation pattern 150 may be provided within the substrate 100 to define the first through fourth unit pixel regions PX1 through PX4. For example, the separation pattern 150 may be provided between the first through fourth unit pixel regions PX1 through PX4 of the substrate 100. The separation pattern 150 may separate the first through fourth unit pixel regions PX1 through PX4 from one another.

The separation pattern 150 may be provided within a deep trench DT. The separation pattern 150 may penetrate the first device isolation pattern 130. At least a portion of the first device isolation pattern 130 may contact the upper sidewalls of the separation pattern 150. The sidewalls and lower surface of the first device isolation pattern 130 and the sidewalls of the separation pattern 150 may have a stepped structure. The depth of the first device isolation pattern 130 may be less than the depth of the separation pattern 150.

The separation pattern 150 may include a first isolation pattern 151, a second isolation pattern 153, and a capping pattern 155.

The first device isolation pattern 130 may be provided within the substrate 100. For example, the first device isolation pattern 130 may be provided within a first shallow trench ST1.

The first device isolation pattern 130 may include a first liner layer 130a, a second liner layer 130b, and a gap-fill layer 130c, which may include different materials.

The first liner layer 130a may include an insulating material. In one or more embodiments, the first liner layer 130a may include SiO.

The second liner layer 130b may include an insulating material. In one or more embodiments, the second liner layer 130b may include SiN, SiCN, or SiOCN.

The gap-fill layer 130c may be disposed on the second liner layer 130b. In one or more embodiments, the gap-fill layer 130c may include SiO.

The second device isolation pattern 170 may be provided within the substrate 100. For example, the second device isolation pattern 170 may be provided within a second shallow trench ST2.

The second device isolation pattern 170 may include an insulating material. In one or more embodiments, the second device isolation pattern 170 may include SiN.

The width of the first device isolation pattern 130 may be greater than the width of the second device isolation pattern 170. In this specification, the term “width” may refer to the length in the direction in which active regions are spaced apart or separated by the first device isolation pattern 130 or the second device isolation pattern 170. The term “width” may also refer to the length measured on a first surface 100a of the substrate 100.

In one or more embodiments, the first device isolation pattern 130 may have a third width W3, and the second device isolation pattern 170 may have a fourth width W4. The minimum value of the third width W3 may be greater than the minimum value of the fourth width W4. For example, the third width W3 may range from 40 nm to 60 nm, and the fourth width W4 may range from 20 nm to 40 nm. Through this, the areas of active regions A1 through A4, B1 through B4, C1 through C4, D1 through D4, and E4 within the first through fourth unit pixel regions PX1 through PX4 can be maximized, thereby providing an image sensor with improved reliability.

The depth of the first device isolation pattern 130 may be less than the depth of the second device isolation pattern 170. In one or more embodiments, the first device isolation pattern 130 may have a first depth D1, and the second device isolation pattern 170 may have a second depth D2. The first depth D1 may be less than the second depth D2. For example, the first depth D1 may range from 250 nm to 350 nm, and the second depth D2 may be greater than 250 nm to 350 nm.

In one or more embodiments, the depth of the second device isolation pattern 170 may correspond to the second depth D2, and the depth of the transfer gate TG may correspond to a third depth D3. The second depth D2 may be greater than the third depth D3. However, the present disclosure is not limited to this. Alternatively, the second depth D2 may be less than the third depth D3. For example, the third depth D3 may range from 420 nm to 450 nm, and the second depth D2 may be greater or less than 420 nm to 450 nm.

The inclined surface 170s of the second device isolation pattern 170 may overlap with the transfer gate TG. The material composition of the second device isolation pattern 170 may differ from that of the first device isolation pattern 130. In one or more embodiments, the first device isolation pattern 130 may include SiO and SiN, and the second device isolation pattern 170 may include SiN but not SiO. However, the present disclosure is not limited to this. Alternatively, the second device isolation pattern 170 may include SiCN or SiOCN.

Through this, the second device isolation pattern 170 can control unexpected electrons that may be generated in adjacent transfer gates TG during processing. That is, the second device isolation pattern 170 can prevent noise caused by dark current within each unit pixel region PX, thereby providing an image sensor with improved reliability.

The first and second device isolation patterns 130 and 170 may divide the active regions within the first through fourth unit pixel regions PX1 through PX4 into first active regions A1 through A4, respectively, second active regions B1 through B4, respectively, third active regions C1 through C4, respectively, fourth active regions D1 through D4, respectively, and fifth active region E4, respectively. The second device isolation pattern 170 may include a first auxiliary device isolation pattern 170a, a second auxiliary device isolation pattern 170b, and a third auxiliary device isolation pattern 170c.

For example, the first auxiliary device isolation pattern 170a may separate the second active region B3 from the active region in the third unit pixel region PX3, and the second active region B4 from the active region in the fourth unit pixel region PX4.

For example, the second auxiliary device isolation pattern 170b may separate the first and third active regions A3 and A4 in the third unit pixel region PX3, and the first and third active regions A4 and C4 in the fourth unit pixel region PX4.

For example, the third auxiliary device isolation pattern 170c may separate the third and fourth active regions C3 and D3 in the third unit pixel region PX3, and the fourth and fifth active regions D4 and E4 in the fourth unit pixel region PX4.

In one or more embodiments, the active regions (A1 through A4, B1 through B4, C1 through C4, D1 through D4, and E4) within the first through fourth unit pixel region PX1 through PX4 may have rounded edges from a planar perspective.

From a planar perspective, the second active regions B1 through B4 may be located in the edge regions of the respective unit pixel regions PX.

In one or more embodiments, the second active regions B1 through B4 within the first through fourth unit pixel regions PX1 through PX4 may include ground regions GND connected to the ground. The ground regions GND may be doped regions. For example, the ground regions GND may have a second conductivity type (e.g., n-type). By defining the second active region B3 using narrower first and second auxiliary device isolation patterns 170a and 170b, the area of the second active region B3 within the third unit pixel region PX3 can be maximized. For example, the area of the ground region GND included in the second active region B3 can be maximized, thereby providing an image sensor with improved reliability.

In one or more embodiments, by separating the active regions within each unit pixel region PX using the narrower second device isolation pattern 170 compared to the first device isolation pattern 130, the areas of the active regions within each unit pixel region PX can be maximized. By maximizing the area of the active regions, the overlap between the active regions and contacts can also be maximized. Through this, an image sensor with improved reliability can be provided.

Source follower transistors SX may include source follower gates SEL and impurity regions DR. The impurity regions DR may be adjacent to the first surface 100a of the substrate 100. Floating diffusion regions FD may be provided in the upper portion of the substrate 100.

Referring to FIG. 34, the third unit pixel region PX3 may be divided into the third and fourth active regions C3 and D3 by the third auxiliary device isolation pattern 170c. A source follower transistor SX may be disposed within the third active region C3. By employing a narrower third auxiliary device isolation pattern 170c compared to the first device isolation pattern 130, the area of the source follower transistor SX can be maximized. As a result, the area of the interface between the gate dielectric film and the silicon channel can be maximized, thereby preventing noise. Through this, an image sensor with improved reliability can be provided.

However, the planar shape of the image sensor according to the present disclosure is not limited to that illustrated in FIG. 32 and may be modified in various manners.

While exemplary embodiments of the present disclosure have been described with reference to the accompanying drawings, the present disclosure is not limited to the described embodiments but may be implemented in various other forms. Those skilled in the art will understand that the present disclosure can be practiced in other specific forms without departing from its technical spirit or essential characteristics. Accordingly, the above-described embodiments should be construed as illustrative rather than restrictive in all respects.

What is claimed is:

1. An image sensor comprising:
a substrate comprising a first surface and a second surface, the first and the second surfaces being on opposite sides of the substrate;
a separation pattern within the substrate, the separation pattern defining a plurality of unit pixel regions, wherein the plurality of unit pixel regions comprises a first unit pixel region;
a first device isolation pattern and a second device isolation pattern within the substrate,
wherein a depth of the second device isolation pattern is greater than a depth of the first device isolation pattern,
wherein the separation pattern penetrates the first device isolation pattern,
wherein the first and the second device isolation patterns define a first active region on the first unit pixel region, and
wherein a first area of the first active region is separated from a second area of the first active region by at least one of the first device isolation pattern and the second device isolation pattern.

2. The image sensor of claim 1, wherein the second area is connected to ground.

3. The image sensor of claim 1, wherein a minimum width of the first device isolation pattern is greater than a minimum width of the second device isolation pattern.

4. The image sensor of claim 1, wherein a first area of the first active region is separated from a second area of the first active region by the second device isolation pattern that extends in a first direction and the second device isolation pattern that extend in a second direction intersecting the first direction.

5. The image sensor of claim 4,
wherein the first area is separated into a third area and a fourth area by the second device isolation pattern.

6. The image sensor of claim 1, wherein a first area of the first active region is separated from a second area of the first active region by the second device isolation pattern that extends in a first direction and the first device isolation pattern that extend in a second direction intersecting the first direction.

7. The image sensor of claim 1,
wherein the first device isolation pattern comprises a first liner layer, a second liner layer, and a gap-fill layer, and
wherein the second device isolation pattern comprises a material that is different from a material of the first liner layer and is the same as a material of the second liner layer.

8. The image sensor of claim 7, wherein the second liner layer comprises any one of SiN, SiCN, or SiOCN.

9. The image sensor of claim 1, wherein an angle formed between an inclined surface of the first device isolation pattern and the first surface is smaller than an angle formed between an inclined surface of the second device isolation pattern and the first surface.

10. The image sensor of claim 1,
wherein the first unit pixel region comprises a transfer gate between the first area and the second device isolation pattern, and
wherein the depth of the second device isolation pattern is greater than a depth of the transfer gate.

11. The image sensor of claim 1,
wherein the first unit pixel region comprises a transfer gate between the first area and the second device isolation pattern, and
wherein the depth of the second device isolation pattern is less than a depth of the transfer gate.

12. The image sensor of claim 11, wherein the transfer gate is a vertical transfer gate.

13. An image sensor comprising:
a substrate comprising a first surface and a second surface, the first and the second surfaces being on opposite sides of the substrate;
a separation pattern within the substrate, the separation pattern defining a plurality of unit pixel regions, wherein the plurality of unit pixel regions comprises a first unit pixel region;
a first device isolation pattern within the substrate; and
a second device isolation pattern within the substrate,
wherein the first and the second device isolation patterns define an active region on the first unit pixel region,
wherein the separation pattern penetrates the first device isolation pattern,
wherein, from a planar perspective, the first unit pixel region comprises: the second device isolation pattern adjacent to an impurity region in a first direction; and a gate electrode adjacent to the impurity region, and
wherein a depth of the second device isolation pattern is greater than a depth of the first device isolation pattern.

14. The image sensor of claim 13, wherein a minimum width of the first device isolation pattern is greater than a minimum width of the second device isolation pattern.

15. The image sensor of claim 13,
wherein the first device isolation pattern comprises a first liner layer, a second liner layer, and a gap-fill layer, and
wherein the second device isolation pattern comprises a material that is different from a material of the first liner layer and the same as a material of the second liner layer.

16. The image sensor of claim 15, wherein the second liner layer comprises any one of SiN, SiCN, or SiOCN.

17. The image sensor of claim 13, wherein an angle formed between an inclined surface of the first device isolation pattern and the first surface is smaller than an angle formed between an inclined surface of the second device isolation pattern and the first surface.

18. The image sensor of claim 13,
wherein the first unit pixel region comprises a first active region connected to ground, and
wherein the first active region is adjacent to the second device isolation pattern.

19. The image sensor of claim 13, wherein the second device isolation pattern overlaps with an inclined surface of the gate electrode.

20. An image sensor comprising:
a substrate comprising a first surface and a second surface, the first and the second surfaces being on opposite sides of the substrate;
a pixel separation pattern within the substrate, the separation pattern defining a plurality of unit pixel regions; and
a plurality of first device isolation patterns; and
a plurality of second device isolation patterns within the substrate,
wherein the plurality of first device isolation patterns and a plurality of second device isolation patterns defining active regions on the plurality of unit pixel regions,
wherein the plurality of unit pixel regions comprises a first unit pixel region and a second unit pixel region separated by the separation pattern,
wherein the first unit pixel region comprises a first active region,
wherein the second unit pixel region comprises a second active region,
wherein, in a first cross-section passing through the first unit pixel region and the second unit pixel region, the separation pattern penetrates a first device isolation pattern of the plurality of first device isolation patterns,
wherein the first active region comprises a first area and a second area separated by the second device isolation patterns,
wherein the second active region comprises a third area and a fourth area separated by the second device isolation patterns,
wherein a depth of the plurality of second device isolation patterns is greater than a depth of the first device isolation pattern,
wherein a minimum width of the first device isolation pattern is greater than a minimum width of the plurality of second device isolation patterns,
wherein the first device isolation pattern comprises a first liner layer, a second liner layer, and a gap-fill layer,
wherein each of the plurality of second device isolation patterns comprises a material that is different from a material of the first liner layer and the same as a material of the second liner layer,
wherein the second liner layer comprises any one of SiN, SiCN, or SiOCN, and
wherein an angle formed between an inclined surface of the first device isolation pattern and the first surface is smaller than an angle formed between inclined surfaces of the plurality of second device isolation patterns and the first surface.
